(19) United States
(12) Patent Application Publication
(10) Pub. No.: US 2016/0172397 A1
(43) Pub. Date: Jun. 16, 2016

(54) Solid State Image Sensor with Low Capacitance Floating Diffusion

(71) Applicants: DARTMOUTH COLLEGE, Hanover, NH (US); Rambus Inc., Sunnyvale, CA (US)

(72) Inventors: Jiaju Ma, West Lebanon, NH (US); Eric R. Fossum, Wolfeboro, NH (US); Michael Guidash, Rochester, NY (US)

(73) Assignees: DARTMOUTH COLLEGE, Hanover, NH (US); Rambus Inc., Sunnyvale, CA (US)

(21) Appl. No.: 14/970,497

(22) Filed: Dec. 15, 2015

Related U.S. Application Data
(60) Provisional application No. 62/092,245, filed on Dec. 15, 2014.

(51) Int. Cl. H01L 27/146

(52) U.S. Cl. CPC H01L 27/14614; H01L 27/1463; H01L 27/14634; H01L 27/14643; H01L 27/1469

(57) ABSTRACT

Some embodiments provide an image sensor having a low capacitance floating diffusion node based on by reducing the width of the overlap between the floating diffusion region and the reset gate of the reset transistor that is configured to selectively reset the potential of the floating diffusion, so as to reduce the overlap capacitance therebetween. The reset gate may be tapered along its length so as to have a minimum width proximal to the FD and a maximum width distal to the floating diffusion, such as near or at a drain region of the reset transistor. The floating diffusion may be defined to have a width less than the minimum floating diffusion width that could be achieved by the minimum definable width of a photoresist window opening used for doping the FD region for the given fabrication process. Shallow trench isolation and/or compensation doping may be used for such definition of the floating diffusion.

### RELATED APPLICATIONS

This application claims the benefit of U.S. Provisional Application No. 62/092,245, filed Dec. 15, 2014, which is hereby incorporated herein by reference in its entirety

### BACKGROUND

The present disclosure relates generally to image sensors and, more particularly, some embodiments of the present invention relate to providing a low capacitance floating diffusion that may be used to provide a high conversion gain pixel well-suited for implementing subdiffraction-limit (SDL) pixels, single-bit photoelectron counting pixels that may be used in a Quanta Image Sensor (QIS), and multi-bit photoelectron counting pixels that may be used in a quantized Digital Integration Sensor (qDIS).

Various solid state imagers, such as charge-coupled devices (CCDs) and CMOS image sensors (CIS), convert photo-charge into a voltage by selectively transferring the photo-charge to a floating diffusion (FD) region that is coupled to (i) the gate of a transistor that forms part of an output amplifier, and (ii) the source of a reset transistor having a reset gate (RG) that is selectively switched to reset the FD to a reference potential set by the drain of the reset transistor. Conversion of the photocharge to a voltage is determined by the FD capacitance.

More specifically, for example, in a conventional CIS pixel with intra-pixel charge transfer, a pinned photodiode (PPD) is typically used as a storage well for storing integrated signal charge (photo-charge, typically photo-electrons). After signal integration, the integrated signal charge is completely transferred via a transfer gate (TG) from the PPD to a floating diffusion (FD) for charge-to-voltage conversion. Just prior to this transfer, a reset transistor is used to reset the FD potential to a reference voltage (reset voltage) that is sufficiently high such that when TG is turned on, signal charge passively and completely flows from the PPD, under the TG, and into the FD. The change in voltage on the FD is buffered by an in-pixel source-follower transistor circuit. The capacity and conversion gain of the FD node depends on its capacitance and its reset voltage.

Various imager applications (e.g., low light) may require reducing this FD capacitance (increasing the conversion gain) to provide the desired sensitivity. Similarly, reducing FD capacitance is also associated with worldwide efforts to further shrink CIS pixels to reduce optics and camera size for the same resolution, and/or to increase pixel count at the same sensor size. During such CIS shrink, great effort is made to maintain the full-well capacity (FWC) of, perhaps, 3000e- or more so that dynamic range and signal-to-noise ratio (SNR) do not suffer. The desire not to degrade dynamic range while shrinking such CIS pixels generally limits the extent to which the FD capacitance may be reduced; nevertheless, such shrinking efforts present challenges for reducing the FD capacitance (increasing the conversion gain).

And yet a significantly greater challenge in reducing the FD capacitance is presented in attempting to employ FD readout configurations of conventional CIS PPD pixels (e.g., such as described above) in the pixels of a QIS, a qDIS, and/or a Digital Integration Sensor (DIS). For example, in some implementations (e.g., QIS), photoconversion of only one or several photons must generate a voltage change that is large enough to be detected, meaning that the charge-to-voltage conversion gain may need to be more than 500 μV/e-, possibly as much as or more than 1000 μV/e-. And, generally, simply scaling a conventional CMOS image sensor pixel will not necessarily provide the sensitivity required for implementing QIS, qDIS, and DIS image sensors.

More specifically, for example, various QIS implementations require single-electron sensitivity (e.g., ˜0.15e- r.m.s.) which can be obtained from high, in-pixel conversion gain, e.g., more than 1000 μV/e-. In addition to small size (e.g., less than 500 nm pitch), jots should also be able to function at low supply voltages (a jot referring to, e.g., a sub-diffraction-limit (SDL) sized, binary-output, single-photelectron-sensitive photoelement of a QIS). In single-bit QIS devices, full-well capacity (FWC) of only 1e- is required, and in multi-bit QIS devices, FWC of perhaps 100e- is sufficient. In contrast, state-of-the-art PPD CISs typically have read noise of about 2e- r.m.s., conversion gain of about 100 μV/e-, pixel pitch of 1-2 μm, full-well capacity (FWC) of at least several thousand electrons, and are thus not presently well-suited for QIS application.

### SUMMARY OF SOME EMBODIMENTS

Some embodiments of the present invention provide for a low capacitance floating diffusion that may be used to implement, for example, a high conversion gain pixel well-suited for applications such as, but not limited to, DIS, qDIS, and QIS image sensors.

While some embodiments of the present invention are well-suited for use in image sensors demanding very high conversion gain (e.g., QIS, qDIS, or other single-bit or multi-bit photoelectron counting sensors), it will be understood in view of the ensuing disclosure that some embodiments of the present invention are also applicable to conventional CISs (e.g., present-day, commercially available CISs for consumer, manufacturing, and/or scientific applications). For example, some embodiments of the present invention may be useful for conventional image sensors at least insofar as such embodiments provide for reduced FD capacitance (increased conversion gain), which may be desired or needed for low-light or other high sensitivity applications and/or for further shrinking conventional CISs (to reduce optics and camera size for the same resolution, and/or to increase pixel count at the same sensor size).

Throughout the description and claims, the following terms take at least the meanings explicitly associated herein, unless the context dictates otherwise. The meanings identified below do not necessarily limit the terms, but merely provide illustrative examples for the terms. The phrase “an embodiment” as used herein does not necessarily refer to the same embodiment, though it may. In addition, the meaning of “a,” “an,” and “the” include plural references; thus, for example, “an embodiment” is not limited to a single embodiment but refers to one or more embodiments. Similarly, the phrase “one embodiment” does not necessarily refer the same embodiment and is not limited to a single embodiment. As used herein, the term “or” is an inclusive “or” operator, and is equivalent to the term “and/or,” unless the context clearly dictates otherwise. The term “based on” is not exclusive and allows for being based on additional factors not described, unless the context clearly dictates otherwise.

Also, as used herein, “n and “p” designations (e.g., as in “n-type,” “p-type,” “n-well,” etc.) are used in ordinary and customary manner to designate donor and acceptor type impurities that promote electron and hole carriers, respectively, as majority carriers. The term “substrate” is to be understood as a semiconductor-based material such as silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “substrates” in the following description, previous process steps may have been utilized to form regions or junctions in the base semiconductor structure or foundation. In addition, the semiconductor need not be silicon-based, but may be based on, for example, silicon-germanium, germanium, or gallium arsenide.

In addition, as used herein, unless the context clearly dictates otherwise, the term “coupled” refers to directly connected or to indirectly connected through one or more intermediate components and, in some contexts, may also denote or include electrically coupled, such as conductively coupled, capacitively coupled, and/or inductively coupled. Further, “conductively coupled” refers to being coupled via one or more intermediate components that permit energy transfer via conduction current, which is capable of including direct current as well as alternating current, while “capacitively coupled” refers to being electrostatically coupled through one or more dielectric media, and possibly also via one or more intervening conductors (e.g., via a series of capacitive components), that permit energy transfer via displacement current and not via direct current. Those skilled in the art will further understand that elements may be capacitively coupled intentionally or unintentionally (e.g., parasitically) and that in some contexts, elements said to be capacitively coupled may refer to intentional capacitive coupling. In addition, those skilled in the art will also understand that in some contexts the term “coupled” may refer to operative coupling, through direct and/or indirect connection. For instance, a conductor (e.g., control line) said to be coupled to the gate of a transistor may refer to the conductor being operable to control the gate potential so as to control the operation of the transistor (e.g., switching the transistor between “on” and “off” states), regardless of whether the conductor is connected to the gate indirectly (e.g., via another transistor, etc.) and/or directly.

For ease of reference and clarity of exposition, unless the context clearly dictates otherwise, the terms “length” and “width” as used herein in reference to a transistor gate (e.g., a reset gate) refer to the dimensions of the transistor gate along respective directions generally parallel and perpendicular to the direction of current flow in the channel between the source and drain regions of the transistor, and particularly with respect to the portion of the transistor gate that overlies the transistor channel and controls the potential therein, as well as with respect to any portions of the transistor gate that may overlap source and drain regions of transistor. Consonant with the foregoing, the terms “length” and “width” as used herein in reference to a transistor channel region (underlying the transistor gate) refer to the dimensions of the transistor channel along respective directions generally parallel and perpendicular to the direction of current flow in the channel between the source and drain regions of the transistor (neglecting any channel-modulation effects associated pinchoff, drain depletion regions, etc.). It will be understood, therefore, that if the transistor gate overlaps its source and drain regions, the transistor gate length will be greater than the channel length by about the sum of the gate/source and gate/drain overlaps along the length direction.

Similarly, for convenience, the terms “width” and “length” as used herein in reference to a source and/or drain region of a transistor refer to respective directions (or dimensions) parallel to the “width” and “length” of the transistor gate, unless the context clearly dictates otherwise. Consonant with the foregoing, as used herein with reference to a floating diffusion region that overlaps and/or is coupled to a neighboring transistor gate (e.g., a transfer gate and/or a reset transistor gate), the term “width” refers to the dimension of the floating diffusion region along a direction parallel to the width of the referenced neighboring transistor gate. In this regard, it will be understood by those skilled in the art that in some implementations perpendicular sides of a generally rectangular (e.g., square) or L-shaped floating diffusion region may be coupled to respective transistor gates (e.g., a transfer gate and a reset gate) that are oriented orthogonally. As such, the “width” of such a floating diffusion may refer to any one of two dimensions, and which of these dimensions is being referred to will be understood in the context of which neighboring transistor gate is being referenced.

As used herein, the terms “length” and “width (or variants thereof; e.g., lengthwise, widthwise) do not denote or connote that the length is necessarily greater (or less) than the width in size, unless the context clearly indicates otherwise. The length of a feature may be greater than, less than, or equal to the width of the feature.

In addition, the term “taper” (or variants thereof; e.g., tapered) as used herein in the context of a transistor channel region (and/or overlying gate) refers to a monotonic increase in channel width (and/or overlying gate) going from a first width to a second increased width, with the change occurring in one or more steps, and/or gradually through one or more angled increases (of equal or different angles) of width over at least a portion of the channel (or gate) length, consistent with illustrative embodiments of the present disclosure.

It will be appreciated by those skilled in the art that the foregoing brief description and the following detailed description with respect to the drawings are illustrative and explanatory of some embodiments of the present invention, and are neither representative nor inclusive of all subject matter and embodiments within the scope of the present invention, nor intended to be restrictive or characterizing of the present invention or limiting of the advantages which can be achieved by embodiments of the present invention, nor intended to require that the present invention necessarily provide one or more of the advantages described herein with respect to some embodiments. Thus, the accompanying drawings, referred to herein and constituting a part hereof, illustrate some embodiments of the invention, and, together with the detailed description, serve to explain principles of some embodiments of the invention.

### BRIEF DESCRIPTION OF THE DRAWINGS

Aspects, features, and advantages of some embodiments of the invention, both as to structure and operation, will be understood and will become more readily apparent in view of the following description of non-limiting and non-exclusive embodiments in conjunction with the accompanying drawings, in which like reference numerals designate the same or similar parts throughout the various figures, and wherein:

FIG. 1 shows an illustrative plan (e.g., layout) view of a portion of an image sensor pixel, in accordance with some embodiments of the present invention;

FIG. 2 shows an illustrative plan (e.g., layout) view of a portion of an image sensor pixel, in accordance with some embodiments of the present invention;

FIG. 3 shows an illustrative plan (e.g., layout) view of a portion of an image sensor pixel, in accordance with some embodiments of the present invention;

FIG. 4 shows an illustrative plan (e.g., layout) view of a portion of an image sensor pixel, in accordance with some embodiments of the present invention;

FIG. 5 shows an illustrative plan (e.g., layout) view of a portion of an image sensor pixel, in accordance with some embodiments of the present invention;

FIG. 6 shows an illustrative plan (e.g., layout) view of a portion of an image sensor pixel, in accordance with some embodiments of the present invention;

FIG. 7 depicts an illustrative plan (e.g., layout) view of a portion of a low-full-well-capacity pump-gate pixel wherein the storage region is disposed beneath the transfer gate, and wherein the floating diffusion does not overlap the transfer gate, in accordance with some embodiments of the present invention;

FIG. 8 is a plan (e.g., layout) view of a distal-floating-diffusion pump-gate jot, similar to the illustrative embodiment of FIG. 7, but using compensation doping rather than STI to constrain the floating diffusion width, in accordance with some embodiments of the present invention; and

FIG. 9 is a schematic illustration of the compensation doping scheme according to the illustrative FIG. 8 embodiment, as depicted with respect to a cross-sectional view at A-A′ in FIG. 8, in accordance with some embodiments of the present invention.

### DETAILED DESCRIPTION OF SOME EMBODIMENTS

Briefly, as will be understood from the ensuing disclosure, some embodiments of the present invention provide an image sensor (e.g., CIS) having a floating diffusion with reduced capacitance (and thus increased conversion gain) at least by reducing the width of the overlap between the floating diffusion region and the reset gate of the reset transistor that is configured to selectively reset the potential of the floating diffusion, so as to reduce the overlap capacitance therebetween.

More specifically, as will be further understood by those skilled in the art, in some illustrative embodiments, to reduce the overlap width of the FD and the reset gate, the FD width is made less than the minimum FD width that could be achieved by the minimum definable width of the photoresist window opening used for doping (e.g., by implanting) the FD region for the given fabrication process. For ease of reference, a width less than this “minimum FD width” as set forth in the previous sentence is said to be a “sub-dopant-patterning-resolution” width. For example, as further described below, such a sub-dopant-patterning-resolution FD width may be defined (e.g., delimited, constrained, or reduced, etc.) by using shallow trench isolation (STI) or by compensation doping, as further described below. This reduction in the FD width (e.g., compared to the FD width that could be achieved by the minimum definable width of the dopant-patterning photoresist window opening) not only allows for reducing the overlap width (and hence overlap capacitance) between the FD and reset gate, but also provides for reducing the FD diffusion capacitance by reducing the FD area.

In addition, in some embodiments having a sub-dopant-patterning-resolution FD width, the width of the channel of the reset gate adjacent to the FD is also defined by STI to have a minimum width equal to the width of the FD.

And in some embodiments, the width of the channel (and, correspondingly, the width of the reset gate overlying the channel) is tapered along its length so as to have a minimum width adjacent to the FD and a maximum width adjacent to a drain region at the end of the channel opposite to the FD. Consonant with the hereinabove clarification of the term “taper,” it will be understood that the transition of the channel (and thus overlying reset gate) from the minimum width to the maximum width may begin at any point along the length of the channel (reset gate), and may comprise one or more angled (sloped) transitions (which need not be contiguous nor have the same angles) and/or one or more step-wise (e.g., 90 degree) transitions.

Such channel tapering may provide for ensuring that the desired reset transistor channel conductance is provided while employing a narrow-width (e.g., sub-dopant-patterning-resolution) FD. Alternatively or additionally, such channel tapering may reduce partition noise, due to 3D effects associated with the channel width being wider on the reset drain side causing carriers to tend to flow to the reset drain (RD) rather than the FD when the reset gate is “On.”

In addition, regardless of whether the channel width is tapered, in some embodiments the drain region at the end of the channel opposite to the FD-adjacent end has a width that is greater than the width of the FD. Even if the channel width adjacent to the RD is narrower than the RD width, fringing fields associated with the RD may contribute to an increase in the channel conductivity.

As will be further understood in view of the present disclosure, in some embodiments an image sensor pixel comprises a sub-dopant-patterning-resolution width FD region, and a reset gate that extends lengthwise between (i) a first end portion thereof that overlaps a lengthwise portion of the floating diffusion over the entire width of the FD, and (ii) a second end portion thereof that overlaps a lengthwise portion of a drain region over a full width of the drain region, wherein the width of the overlapped drain region is greater than the width of the overlapped FD region. The channel, and thus the reset gate overlying the channel, may be tapered such that the width of the overlap of the second end portion and the drain region is greater than the width of the sub-dopant-patterning-resolution width FD. Alternatively, in some embodiments, the reset gate channel (and thus, the reset gate) may not be tapered, and its width may be, for example, equal to the FD width, or greater than the FD width but less than the width of the drain region

For example, as will be further understood, some embodiments provide an image sensor pixel that includes: a floating diffusion region for selectively converting photo-charge transferred thereto into a voltage; and, a reset transistor having a tapered reset gate that extends lengthwise between (i) a first end portion thereof that overlaps with a portion of the floating diffusion, and (ii) a second end portion thereof that overlaps a portion of a drain region, wherein the width of the first end portion of the tapered reset gate is less than the width of the second end portion of the tapered reset gate. Concomitantly, the width of the channel of the reset transistor adjacent to the floating diffusion is less than the reset transistor channel width adjacent to the drain region.

In a conventional 4T pixel, the total capacitance of the FD primarily comprises five components: (1) the diffusion capacitance of FD; (2) the diffusion capacitance of the source of the reset transistor, if the FD is connected to the reset transistors by wires; (3) the effective gate capacitance of the source follower; (4) the overlap capacitance between the reset gate (RG) and FD; and (5) the overlap capacitance between the transfer gate (TG) and FD. The present inventors recognized that the overlap capacitance between the reset gate and the floating diffusion can be a significant portion of the capacitance seen by the floating diffusion in pixels with intra-charge transfer to the floating diffusion for charge-to-voltage conversion, and particularly that this portion may increase as the pixel is scaled to smaller technology nodes. Accordingly, adapting floating diffusion readout circuitry for implementing novel image sensor concepts such as DIS and QIS requires reducing such overlap capacitance. As will be understood by those skilled in the art in view of the present disclosure, while some embodiments of the present invention are well-suited for implementing novel image sensor concepts such as DIS and QIS, various embodiments also have myriad applications in more conventional high sensitivity (e.g., low light) image sensors.

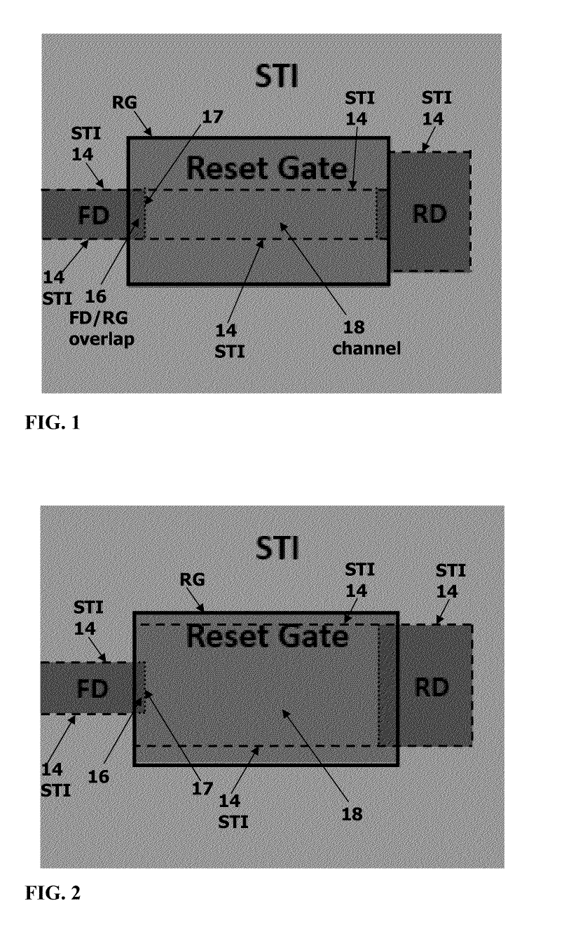

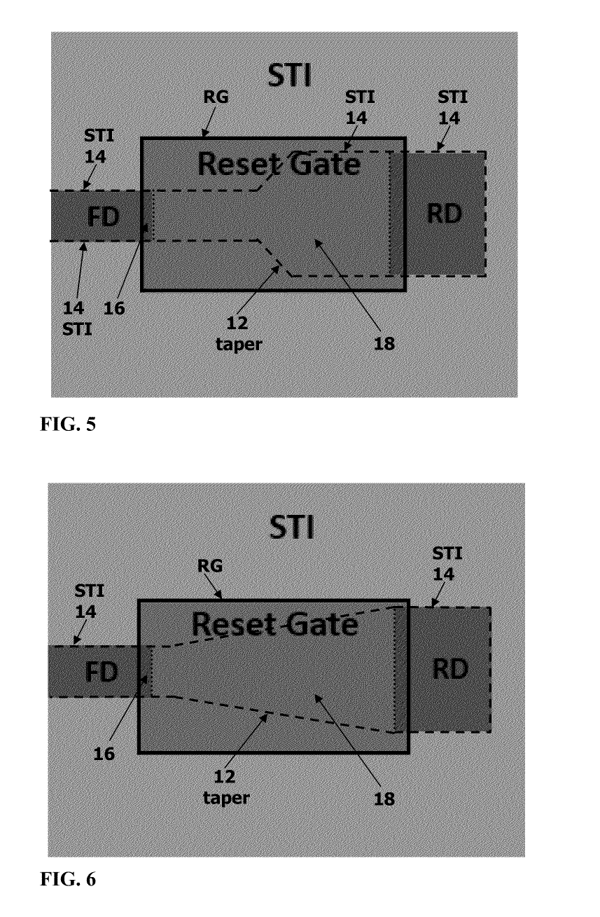

In accordance with some embodiments, FIGS. 1-6 schematically depict plan (e.g., layout) views of various illustrative embodiments of a portion of readout circuitry for an image sensor; for example, FIGS. 1-6 may correspond to a portion of the in-pixel readout circuitry that may be included in a conventional CIS, or a QIS, or a qDIS, etc. More specifically, for clarity of exposition, FIGS. 1-6 do not show the entire architecture of a whole pixel, but focus primarily on illustrative embodiments of floating diffusion, reset gate, and drain portion configurations that may be employed in image sensor readout (e.g., implemented within the in-pixel readout circuitry of a conventional CIS, or a QIS, or a qDIS, or a DIS), in accordance with providing for reduced overlap capacitance between the reset gate and the FD region. As understood by those skilled in the art, a pixel includes additional circuitry/devices, such as transistors/gates (e.g., transfer gates, select transistor, source-follower (SF)), photo-charge storage node (e.g., a PPD), and interconnect structures (e.g. connecting the FD to the SF gate, etc.), and an image sensor may comprise an array of such pixels (e.g., pixels arranged in rows and columns).

For ease of reference, in FIGS. 1-6, gate layer patterns/features (e.g., reset gate pattern/conductor RG) are shown bounded by solid lines, STI regions/boundaries are indicated by dashed lines (e.g., STI pattern boundaries 14), regions of overlap between gate layer (gate stack) and diffusions are illustratively delimited in part by a dotted line 17. As may be seen, a channel region 18 is disposed between the FD and RD regions. And while the reset gate conductor is generally denoted by RG (delineated by the solid line), it will be understood that the reset gate geometry (e.g., length and width; tapered boundary 12) is delineated with respect to the underlying channel region 18, and the RG/FD overlap capacitance corresponds to the FD/RG overlap areas 16 where the diffusions extend under the gate stack adjacent to the channel.

As discussed above, some embodiments of the present disclosure allow for shrinking the size of the FD to less than the minimum size as would be limited by the smallest feature size of the n+ implant window. In accordance with some embodiments, as shown for example in FIGS. 1-6, STI may be used to constrain the FD width and the channel width of the adjacent reset transistor (e.g., such that the FD width is less than the minimum size as would be limited by the smallest feature size of the n+ implant window for the given process technology/technology node).

For example, in some embodiments, STI etching (e.g., with a tapered region corresponding to the RG/channel region) may be performed in the silicon surrounding the photosensing element before the polysilicon deposition, and the STI may form a narrow fin on the silicon (e.g., corresponding to the FD width). After polysilicon deposition (e.g., to define gate conductors/stacks, such as reset gate (RG) and transfer gate (TG)), a floating diffusion (FD) dose will be implanted into to the fin (and, e.g., into other source/drain regions). The narrow width of the fin may greatly constrain the area size of FD and the effective width of the reset gate (RG), so as to significantly reduce and/or minimize the diffusion capacitance of the FD as well as the overlap capacitance. While the STI delineation may increase the sidewall capacitance of the FD, the total capacitance of FD will still be reduced.

In some such implementations, one concern may be that concomitant shrinking of the reset transistor channel with FD width shrinking may unduly limit the reset transistor conductance for various implementation. Illustrative embodiments below may be employed to address this concern and provide a desired channel conductivity/conductance.

For example, in the illustrative embodiment of FIG. 1, the channel has the same width as FD, but the reset drain (RD) is wider. During reset, the wider RD may provide for a higher potential on the RD side, thus providing for a fringing field effect that will help improve the low conductivity of the channel due to its narrower width.

In the illustrative embodiment of FIG. 2, the channel has the same width as the RD, which is wider than FD; thus, the wider channel provides for higher conductivity.

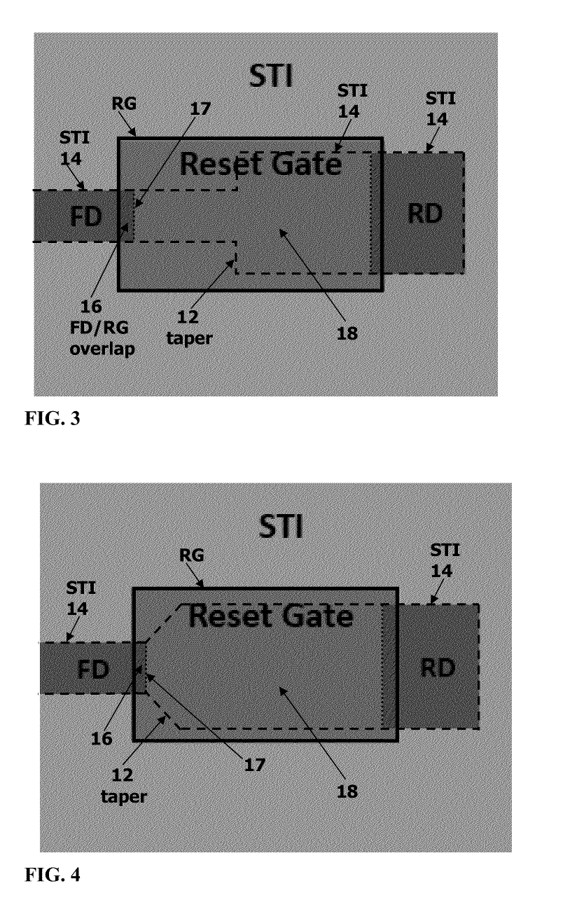

In the illustrative embodiment of FIG. 3, the channel width increases in a single-step within the channel (e.g., about mid-channel), the increased width also providing for increased channel conductance.

It may be appreciated, however, that in various STI fabrication processes, the STI designs in the embodiments of FIGS. 2 and 3 may violate some design rules (e.g., the vertical edge of the STI width change may be smaller than the critical/minimum allowable STI feature size). Accordingly, for this and/or other reason(s), some embodiments may employ a gradual (e.g., not steeply angled) tapered STI approach for increasing the channel width. Various illustrative gradual tapering embodiments are shown in FIGS. 4, 5, and 6. The gradually tapered angle may be any angle, and the taper edge can begin from any point in the channel as long as the reset drain is preferably not tapered. In current CMOS technology design tools, however, the taper angle can only be made to be 45 degrees.

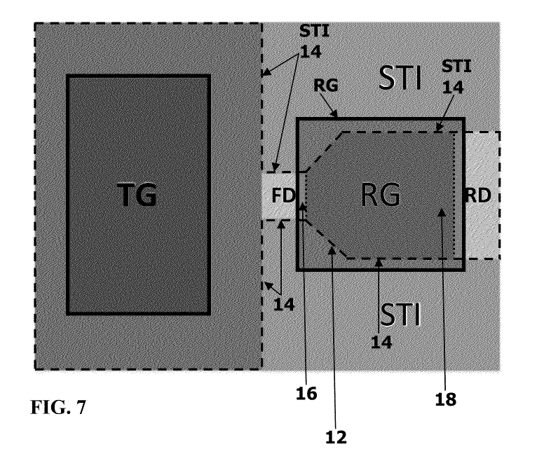

FIG. 7 depicts a schematic plan view of an illustrative embodiment of a portion of a pixel that includes an STI-constrained FD and RG tapering, in accordance with some embodiments of the present disclosure, and as applied to a low-full-well-capacity pump-gate pixel (e.g., a jot of a QIS, comprising an array of such jots) wherein the storage region is disposed beneath the TG, and wherein the FD does not overlap the TG (referred to as a distal FD), which is disclosed in U.S. Provisional Application No. 61/973,825, filed Apr. 1, 2014, entitled “CMOS Image Sensor with Pump Gate and Extremely High Conversion Gain,” which is hereby incorporated by reference herein in its entirety. Such an illustrative embodiment of FIG. 7 is particularly well suited for implementing novel image sensor concepts such as DIS and QIS, and also has many possible future applications in more conventional high sensitivity (low light) image sensors. In accordance with the foregoing, it will be understood that while the illustrative embodiment of FIG. 7 also depicts a transfer gate (TG) (which overlies a buried photodiode), it nevertheless also depicts only a portion of image sensor in-pixel circuitry (which may include, e.g., a row-select and source-follower transistors, as well as interconnect metallization, etc.).

Embodiments of the present disclosure may also be combined with, and applied to, embodiments of low full-well capacity, high conversion gain pixels that comprise a buried-well vertically pinned photodiode having a charge accumulation/storage region disposed substantially beneath the transfer gate (but which do not include a distal FD and/or a pump gate configuration), such as some embodiments as disclosed in international application no. PCT/US14/42015, filed Jun. 11, 2014, entitled “Image Sensor Pixels with Low Full-Well Capacity and Very High Sensitivity, and Image Sensors Having Same,” and in U.S. Provisional Application No. 61/833,701, filed Jun. 11, 2013, entitled “CMOS Image Sensor with Low Full-Well Capacity and High Conversion Gain,” each of which is hereby incorporated herein in its entirety.

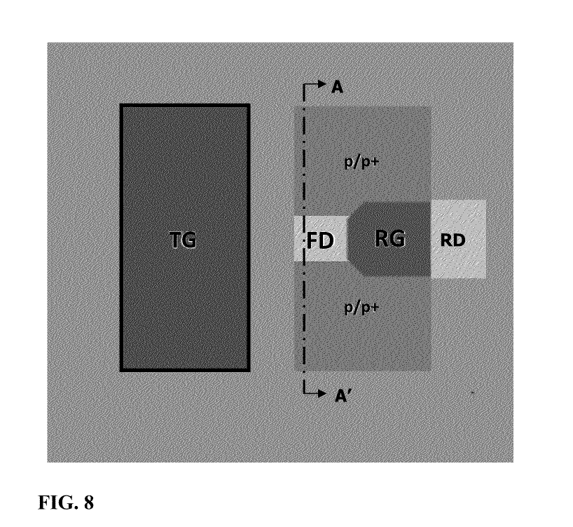

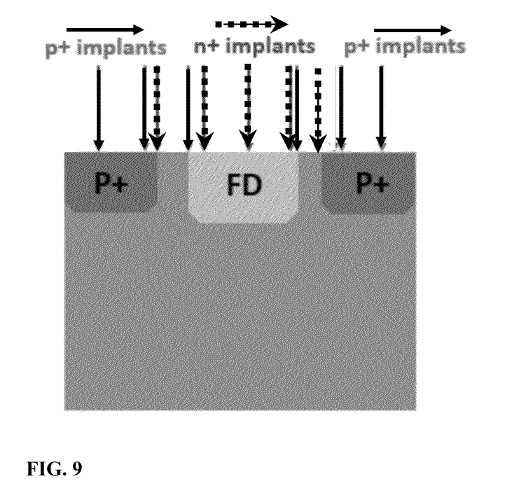

FIGS. 8 and 9 schematically depict another approach (e.g., other than using STI) to shrink the FD size. More specifically, FIG. 8 is a plan view for implementing a distal FD pump gate jot, similar to that referred to in FIG. 7, but using compensation doping rather than STI to constrain the FD width. The compensation doping scheme to narrow the width of a mask-window defined n+ FD region may be understood in view of FIG. 8 together with FIG. 9, which is a schematic illustration of the compensation scheme with respect to a cross-sectional view at A-A′ in FIG. 8. The p+ implant mask will overlap with the n+ implant mask of FD, and compensate n+ doping, so as to shrink the width of the FD. The p+ implant may increase the sidewall junction capacitance of FD, but the diffusion capacitance of FD will be reduced due to smaller area size. The tapered poly gate, shown in FIG. 7, can also reduce the effective overlap capacitance with the RG.

While the present disclosure predominantly focuses on the overlap between the FD and the RG, in view of the ensuing disclosure those skilled in the art will understand that in some embodiments according to the present disclosure, similar principles and configurations may be applied with respect to transfer gate (TG) in various implementations wherein the in-pixel transfer gate may also overlap the floating diffusion region and high conversion gain is desired. By way of example, such embodiments may comprise conventional PPD CIS pixels (e.g., in connection with shrinking/scaling efforts), as well as in embodiments of low full-well capacity, high conversion gain pixels that comprise a buried-well vertically pinned photodiode having a charge accumulation/storage region disposed substantially beneath the transfer gate (but which do not include a distal FD and may not include a pump gate configuration), as disclosed in international application no. PCT/US14/42015, filed Jun. 11, 2014, entitled “Image Sensor Pixels with Low Full-Well Capacity and Very High Sensitivity, and Image Sensors Having Same,” and in U.S. Provisional Application No. 61/833,701, filed Jun. 11, 2013, entitled “CMOS Image Sensor with Low Full-Well Capacity and High Conversion Gain,” each of which is hereby incorporated herein in its entirety.

The present invention has been illustrated and described with respect to some specific embodiments thereof, which embodiments are merely illustrative of some of the principles of some embodiments of the invention and are not intended to be exclusive or otherwise limiting embodiments. Accordingly, although the above description of illustrative embodiments of the present invention, as well as various illustrative modifications and features thereof, provides many specificities, these enabling details should not be construed as limiting the scope of the invention, and it will be readily understood by those persons skilled in the art that the present invention is susceptible to many modifications, adaptations, variations, omissions, additions, and equivalent implementations without departing from this scope and without diminishing its attendant advantages. For instance, except to the extent necessary or inherent in the processes themselves, no particular order to steps or stages of methods or processes described in this disclosure, including the figures, is implied. In many cases the order of process steps may be varied, and various illustrative steps may be combined, altered, or omitted, without changing the purpose, effect or import of the methods described. Similarly, the structure and/or function of a component may be combined into a single component or divided among two or more components. It is further noted that the terms and expressions have been used as terms of description and not terms of limitation. There is no intention to use the terms or expressions to exclude any equivalents of features shown and described or portions thereof. Additionally, the present invention may be practiced without necessarily providing one or more of the advantages described herein or otherwise understood in view of the disclosure and/or that may be realized in some embodiments thereof. It is therefore intended that the present invention is not limited to the disclosed embodiments but should be defined in accordance with claims that are based on the present disclosure, as such claims may be presented herein and/or in any patent applications claiming priority to, based on, and/or corresponding to the present disclosure.

What is claimed is:

1. An image sensor comprising a plurality of pixels, at least one pixel comprising:
a floating diffusion formed in a semiconductor substrate; and
a reset transistor having a reset gate that is operable to selectively reset the potential of the floating diffusion; and
wherein (i) the reset gate is tapered such that its width proximal to the floating diffusion is less than its width distal to the floating diffusion, and/or (ii) the floating diffusion has a sub-dopant-patterning-resolution width.

2. The image sensor according to claim 1, wherein the floating diffusion has a sub-dopant-patterning-resolution width, and the sub-dopant-patterning-resolution width of the floating diffusion is defined using shallow trench isolation.

3. The image sensor according to claim 1, wherein the floating diffusion has a sub-dopant-patterning-resolution width, and the sub-dopant-patterning-resolution width of the floating diffusion is defined using compensation doping.

4. The image sensor according to claim 1, wherein the reset gate overlaps the floating diffusion.

5. The image sensor according to claim 1, wherein the reset gate is tapered such that its width proximal to the floating diffusion is less than its width distal to the floating diffusion.

6. The image sensor according to claim 5, wherein the floating diffusion has a sub-dopant-patterning-resolution width.

7. The image sensor according to claim 6, wherein the width of the floating diffusion is defined using shallow trench isolation.

8. The image sensor according to claim 6, wherein the width of the floating diffusion is defined using compensation doping.

9. The image sensor according to claim 6, wherein the reset gate that overlaps the floating diffusion.

10. The image sensor according to claim 1, wherein the reset gate extends lengthwise between (i) a first end portion thereof that overlaps a lengthwise portion of the floating diffusion over the entire width of the floating diffusion, and (ii) a second end portion thereof that overlaps a lengthwise portion of a drain region over a full width of the drain region, wherein the width of the overlapped drain region is greater than the width of the overlapped FD region.

11. The image sensor according to claim 10, wherein the reset transistor has a channel region underlying the reset gate, wherein at least a portion of the channel region has a sub-dopant-patterning-resolution width, and the channel region is defined by shallow trench isolation.

12. The image sensor according to claim 1, wherein the floating diffusion has a sub-dopant-patterning-resolution width, and wherein the reset gate is not tapered.

13. The image sensor according to claim 12, wherein the reset gate has a width equal to the floating diffusion width.

13. The image sensor according to claim 12, wherein the reset gate extends lengthwise between (i) a first end portion thereof that overlaps a lengthwise portion of the floating diffusion over the entire width of the floating diffusion, and (ii) a second end portion thereof that overlaps a lengthwise portion of a drain region, wherein the reset transistor has a channel region underlying the reset gate, wherein the channel region has a sub-dopant-patterning-resolution width that is defined by shallow trench isolation and corresponds to the reset gate width.

14. The image sensor according to claim 13, wherein the channel region width is equal to the floating diffusion width.

15. A method for providing an image sensor comprising a plurality of pixels, the method comprising:
forming a floating diffusion in a semiconductor substrate; and
providing a reset transistor having a reset gate that is configured to selectively reset the potential of the floating diffusion; and
wherein (i) the reset gate is tapered such that its width proximal to the floating diffusion is less than its width distal to the floating diffusion, and/or (ii) the floating diffusion has a sub-dopant-patterning-resolution width.

16. The method according to claim 15, wherein the reset gate is tapered such that its width proximal to the floating diffusion is less than its width distal to the floating diffusion.

17. The method according to claim 15, wherein the floating diffusion has a sub-dopant-patterning-resolution width.

18. The method according to claim 15, wherein the (i) the reset gate is tapered such that its width proximal to the floating diffusion is less than its width distal to the floating diffusion, and (ii) the floating diffusion has a sub-dopant-patterning-resolution width.
